(19) United States
(12) Patent Application Publication
(10) Pub. No.: US 2024/0055281 A1
(43) Pub. Date: Feb. 15, 2024

(54) SUBSTRATE PROCESSING METHOD, METHOD FOR CONTROLLING SUBSTRATE PROCESSING METHOD AND SUBSTRATE PROCESSING APPARATUS

(71) Applicant: SEMES CO., LTD., Cheonan-si (KR)

(72) Inventors: Sung Yong LEE, Yongin-si (KR); Myung Hwan OH, Seongnam-si (KR)

(73) Assignee: SEMES CO., LTD., Cheonan-si (KR)

(21) Appl. No.: 18/166,029

(22) Filed: Feb. 8, 2023

(30) Foreign Application Priority Data
Aug. 12, 2022 (KR) 10-2022-0101049

(51) Int. Cl. H01L 21/67

(52) U.S. Cl. CPC H01L 21/67248; H01L 21/67103; H01L 21/6715

(57) ABSTRACT

The inventive concept provides a substrate treating method. The substrate treating method includes measuring a temperature of a plurality of heaters installed on a heating plate for heating a substrate; and heating the substrate by adjusting an output of the heater based on a difference between a measured temperature of each heater and a target temperature of each heater which was previously modelled, and wherein a target temperature of a first heater among the heaters at a first time point is set differently from the target temperature of the first heater at a second time point which is later than the first time point.

### CROSS-REFERENCE TO RELATED APPLICATIONS

A claim for priority under 35 U.S.C. § 119 is made to Korean Patent Application No. 10-2022-0101049 filed on Aug. 12, 2022, in the Korean Intellectual Property Office, the entire contents of which are hereby incorporated by reference.

### TECHNICAL FIELD

Embodiments of the inventive concept described herein relate to a substrate treating method and a substrate treating apparatus, more specifically, a substrate treating method and substrate treating apparatus for treating a substrate by heating the substrate.

### BACKGROUND

In order to manufacture a semiconductor element or a flat display panel, various processes such as a photolithography process, an etching process, an ashing process, a thin film deposition process, and a cleaning process are performed. Among these processes, the photolithography process includes a coating process of forming a coating film by supplying a photoresist liquid on a substrate such as a wafer, an exposing process of irradiating a light using a mask on the coating film formed on the substrate, and a developing process of supplying a developing liquid to the coating film on which the coating process is formed to acquire a desired pattern on the substrate.

In addition, to stabilize the coating film and a pattern formed on the substrate, a heat treatment process for heating the substrate may be performed between the coating process and the exposing process, between the exposing process and the developing process, and after the developing process. In this heat treatment process, the substrate is placed on a heating plate on which a heater generating a heat is installed, and the heater generates the heat to heat the substrate.

Meanwhile, an output of the heater may be feedback-controlled so that the heater installed on the heating plate may heat the substrate at a constant temperature. Specifically, in order for the heater to heat the substrate to a constant temperature, a target temperature of the heater can be set at a set temperature (e.g., 80° C.), and a temperature of the heater can be kept constant by increasing or decreasing the output of the heater if a measured temperature differs from the target temperature. If the heater is constantly kept at the target temperature, an amount of heat per unit time transmitted to the substrate is also kept constant, so the substrate is heated to a constant temperature.

Recently, in addition to heating the substrate to the constant temperature, a plurality of heaters are installed on the heating plate so that the substrate may be uniformly heated for each region. The output of each heater may be individually controlled.

FIG. 1 is a graph showing a temperature change over time of heaters if a substrate is placed on a heating plate at which a plurality of heaters are installed.

Referring to FIG. 1, the plurality of heaters may be installed on the heating plate. For example, a first heater H1, a second heater H2, and a third heater H3 may be installed on the heating plate. The first heater H1, the second heater H2, and the third heater H3 may be installed at different positions to heat different regions of the substrate. The target temperatures of the first heater H1 to the third heater H3 may be set to a predetermined set temperature TT.

In the pre-treatment section S0, t0 to t1, which is a section before the substrate is placed on the heating plate, temperatures of the heaters H1, H2, and H3 may be constantly maintained at the target temperature by a feedback control described above.

The heating section S1, t1˜, which is a section after the substrate is placed on the heating plate, includes a transitional period S1a, t1˜t2 and a stabilizing period S12, t2˜. The substrate is placed on the heating plate at a relatively lower temperature than the heating plate. If a low-temperature substrate is placed on the heating plate, the temperatures of the heaters H1, H2, and H3 which have been constantly maintained at the target temperature may change. In the transitional period S12, the temperatures of the heaters H1, H2, and H3 are undershooted from the set temperature TT by the substrate having a low temperature, and then overshooted from the set temperature TT again. Thereafter, the temperatures of the heaters H1, H2, and H3 may be adjusted to the set temperature TT again to enter the stabilizing period S1b.

The temperatures of the heaters H1, H2, and H3 change rapidly during the transitional period S1a. In addition, a temperature deviation between the heaters H1, H2, and H3 is large during the transitional period S1a. A temperature change of the heaters H1, H2, and H3 generated in the transitional period S1a occurs if a substrate having a relatively low temperature is placed on the heating plate. In the transitional period S1a, a temperature difference of the heaters H1, H2, H3 may occur because a temperature of each region of the substrate on the heating plate is different from each other, and even if the temperature of each region of the substrate is the same, it may be caused by a difference in unique physical characteristics of each of the heaters H1, H2, H3.

The heaters H1, H2, and H3, which were constantly maintained at a set temperature TT with little temperature deviation in the pre-treatment section S0, change their temperatures differently from each other as the substrate is placed on the heating plate. The outputs of the heaters H1, H2, and H3 are each controlled differently so that a temperature thereof may be adjusted to the target temperature TT again.

In order for the heat per unit time transferred by the heaters H1, H2, and H3 for each region of the substrate to be the same, temperature changes of the heaters H1, H2, and H3 must match each other. After t2, which is a time point at which the temperatures of the heaters H1, H2, and H3 are each adjusted to the set temperature TT again, the amount of heat per unit time transferred by each of the heaters H1, H2, and H3 to the substrate is the same. However, before the temperature of the heaters H1, H2, and H3 is adjusted to the set temperature TT, the temperature changes of the heaters H1, H2, and H3 do not match, so a heat transfer per unit time of each of the heaters H1, H2, and H3 is different for each region of the substrate.

If a time in which the temperature changes of the heaters H1, H2, and H3 do not match increases, a period in which a heat transferred per unit time for each region of the substrate increases, which makes it difficult to uniformly treat the substrate. In particular, since exposing processes using an ArF, an EUV, etc. which require a high critical dimension uniformity require a high precision, it is required to minimize a time when the temperature changes of the heaters H1, H2, and H3 do not match, that is, a time when a temperature deviation is different for each region of the substrate.

### SUMMARY

Embodiments of the inventive concept provide a substrate treating method and a substrate treating apparatus for efficiently treating a substrate.

Embodiments of the inventive concept provide a substrate treating method and a substrate treating apparatus for letting a temperature profile of heaters quickly match, after a substrate is placed on a heating plate.

Embodiments of the inventive concept provide a substrate treating method and a substrate treating apparatus for uniformly heating a substrate.

The technical objectives of the inventive concept are not limited to the above-mentioned ones, and the other unmentioned technical objects will become apparent to those skilled in the art from the following description.

The inventive concept provides a substrate treating method. The substrate treating method includes measuring a temperature of a plurality of heaters installed on a heating plate for heating a substrate; and heating the substrate by adjusting an output of the heater based on a difference between a measured temperature of each heater and a target temperature of each heater which was previously modelled, and wherein a target temperature of a first heater among the heaters at a first time point is set differently from the target temperature of the first heater at a second time point which is later than the first time point.

In an embodiment, the target temperature of the first heater among the heaters at the first time point is set lower than the target temperature of the first heater at the second time point.

In an embodiment, the target temperature of the second heater among the heaters at the first time point is set differently from the target temperature of the second heater at the second time point.

In an embodiment, the target temperature of the second heater among the heaters at the first time point is set higher than the target temperature of the second heater at the second time point.

In an embodiment, the first heater has a temperature drop smaller than the second heater if the substrate is seated on the heating plate.

In an embodiment, the target temperature of the first heater and the second heater at the first time point, is based on at least one among a rise speed and a drop speed of a temperature of the second heater, and a temperature drop if the substrate is seated on the heating plate.

In an embodiment, the measured temperature of each heater is calculated based on a measured resistance value of the heater.

In an embodiment, the substrate is heated by being seated on the heating plate after a coating process of coating a photoresist liquid on the substrate is performed and a subsequent exposing process is performed after the coating process.

In an embodiment, the first time point belongs to a transitional period which is an early period among a substrate heating section and the second time point belongs to a stabilization period among a later period among the substrate heating section.

In an embodiment, a temperature change of the heater at the transitional period is larger than a temperature change of the heater in the stabilization period.

The inventive concept provides a method for controlling a substrate treating apparatus. The method for controlling a substrate treating apparatus includes measuring a temperature of a plurality of heaters installed on a heating plate; adjusting an output of the heater based on a difference between a measured temperature of each heater and a target temperature of each heater which was previously modelled, and wherein a target temperature of a first heater among the heaters at a first time point is set differently from the target temperature of the first heater at a second time point which is later than the first time point.

In an embodiment, the first time point belongs to a transitional period which is an early period among a substrate heating section and the second time point belongs to a stabilization period among a later period among the substrate heating section.

In an embodiment, the target temperature of the first heater among the heaters at the first time point is set lower than the target temperature of the first heater at the second time point.

In an embodiment, the target temperature of the second heater among the heaters at the first time point is set higher than the target temperature of the second heater at the second time point.

In an embodiment, the first heater has a temperature drop smaller than the second heater if the substrate is seated on the heating plate.

In an embodiment, the target temperature of the first heater and the second heater at the first time point, is based on at least one among a rise speed and a drop speed of a temperature of the second heater, and a temperature drop if the substrate is seated on the heating plate.

The inventive concept provides a substrate treating apparatus. The substrate treating apparatus includes a liquid treating unit configured to liquid treat a substrate; a heating unit configured to heat a substrate which is treated at the liquid treating unit; and a control unit configured to control the heating unit, and wherein the heating unit comprises: a housing forming a heating space; a heating plate supporting the substrate at the heating space; a plurality of heaters installed at the heating plate; a power source applying a power to the heaters; and a temperature controller controlling a power applied to the heaters by the power source, and wherein the control unit stores a target temperature profile which is a change of a target temperature based on a time corresponding to each heater; and controls the temperature controller by measuring a temperature of the heater and adjusts an output of the heater based on a difference between a measured temperature of the heater and a target temperature of the heater to heat the substrate, and wherein a first target temperature profile which corresponds to a first heater among the heaters is set lower to a target temperature of a second time point which is lower than a first time point.

In an embodiment, for a second target temperature profile of a second heater among the heaters a target temperature of the first time point is set higher than a target temperature of the second time point.

In an embodiment, the first heater is a heater having a temperature drop which is smaller than the second heater if the substrate is seated on the heating plate.

In an embodiment, the target temperature of the first heater and the second heater at the first time point, is based on at least one among a rise speed and a drop speed of a temperature of the first heater and the second heater, and a temperature drop if the substrate is seated on the heating plate.

According to an embodiment of the inventive concept, a substrate may be efficiently treated.

According to an embodiment of the inventive concept, a temperature profile of heaters may be quickly matched after a substrate is placed on a heating plate.

According to an embodiment of the inventive concept, a substrate may be uniformly heated.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a graph showing a temperature change over time of heaters if a substrate is placed on a heating plate at which a plurality of heaters are installed.

FIG. 2 schematically illustrates a substrate treating apparatus according to an embodiment of the inventive concept.

FIG. 3 is a cross-sectional view of a heating unit of FIG. 2.

FIG. 4 is a view showing an installation position of a heater installed at each region of the heating plate of FIG. 3.

FIG. 5 is a flowchart schematically showing a substrate treating method according to an embodiment of the inventive concept.

FIG. 6 is a block view showing a modeling step and a heating step of FIG. 5.

FIG. 7 is a graph showing a modeling method of a target temperature profile generated in the modeling step of FIG. 5.

FIG. 8 is a graph schematically showing a first target temperature profile of a first heater generated by the modeling method shown in FIG. 7.

FIG. 9 is a graph schematically showing a second target temperature profile of a second heater generated by the modeling method shown in FIG. 7.

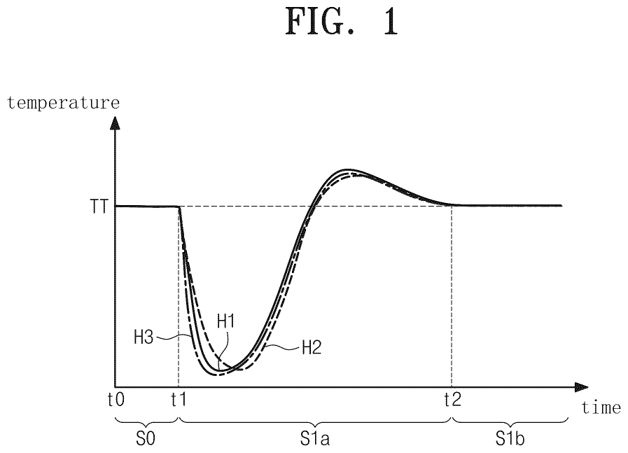

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

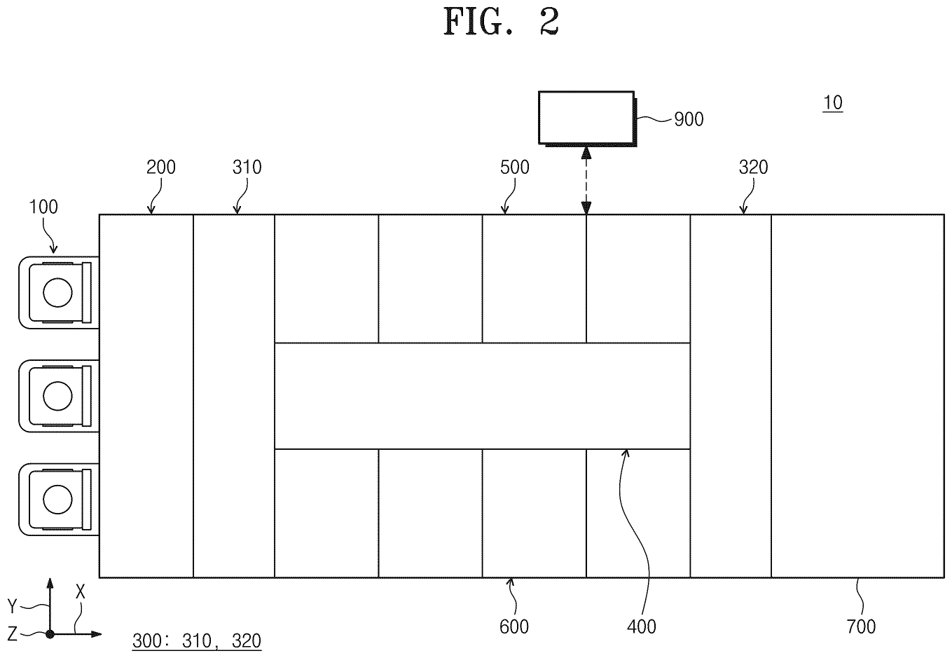

Hereinafter, an embodiment of the inventive concept will be described with reference to FIG. 2 to FIG. 9.

FIG. 2 schematically illustrates a substrate treating apparatus according to an embodiment of the inventive concept.

Referring to FIG. 2, the substrate treating apparatus 10 according to an embodiment of the inventive concept may include a load port unit 100, an index unit 200, a buffer unit 300, a transfer unit 400, a liquid treating unit 500, a heating unit 600, an interface unit 700, and a control unit 900. Hereinafter, a direction in which the load port unit 100 and the index unit 200 are arranged may be defined as a first direction X, a direction perpendicular to the first direction X may be defined as a second direction Y, a direction perpendicular to the first direction X and the second direction Y may be defined as a third direction Z.

In the load port unit 100, a container in which a substrate such as a wafer or the like is stored may be placed. In the load port unit 100, a container in which a substrate such as FOUP is stored may be placed. The load port unit 100 may have a plurality of load ports. The plurality of load ports may be arranged in the second direction Y when viewed from above the substrate treating apparatus 10.

A transport vehicle such as an Overhead Transport (OHT) may transfer the container to a load port of the load port unit 100. In addition, a transfer robot such as an Auto Vehicle Robot (AVR) may transfer the container to the load port of the load port unit 100.

The index unit 200 may be disposed between the load port unit 100 and a front buffer unit 310 of the buffer unit 300 to be described later. The index unit 200 may be provided with an index robot (not shown) which takes the substrate out of the container seated on the load port of the load port unit 100 and transfers it to the front buffer unit 310 to be described later.

The buffer unit 300 may include a front buffer unit 310 and a rear buffer unit 320. The front buffer unit 310 may be disposed between the index unit 200 and the transfer unit 400 to be described later. The rear buffer unit 320 may be disposed between the transfer unit 400 to be described later and the interface unit 700 to be described later. The front buffer unit 310 and the rear buffer unit 320 may include a storage shelf (not shown) capable of temporarily storing a plurality of substrates. The storage shelf may include a plurality of support members disposed along the third direction Z. In addition, the front buffer unit 310 and the rear buffer unit 320 may include a buffer robot (not shown) which transfers a substrate seated at a first position of the storage shelf to a second position which is different from the first position of the storage shelf (e.g., different height).

The transfer unit 400 may transfer the substrate. The transfer unit 400 may transfer the substrate between the front buffer unit 310, the liquid treatment unit 500 to be described later, the heating unit 600 to be described later, and the rear buffer unit 320. The transfer unit 400 may take out the substrate temporarily stored in the front buffer unit 310 and transfer the substrate to the liquid treatment unit 500. The transfer unit 400 may transfer the substrate from the liquid treatment unit 500 and transfer the substrate to the heating unit 600. The transfer unit 400 may transfer the substrate from the heating unit 600 and transfer the substrate to the rear buffer unit 320. Conversely, the substrate may be transferred from the rear buffer unit 320 to the heating unit 600. In addition, the substrate can be transferred from the heating unit 600 to the liquid treatment unit 500. In addition, the substrate may be transferred from the heating unit 600 to the front buffer unit 310.

The transfer unit 400 may include a hand on which the substrate is placed, an arm for changing a position of the hand, and a moving rail for changing a position of the arm. The moving rail may change the position of the arm along the first direction X and/or the third direction Z.

The liquid treatment unit 500 may liquid-treat the substrate. The liquid treatment unit 500 may treat the substrate by supplying a liquid to a rotating substrate. A plurality of liquid treatment units 500 may be provided. The liquid treating units 500 may be disposed along the first direction X. In addition, the liquid treatment units 500 may be provided stacked along the third direction Z. The liquid treating units 500 may be disposed on a side of the transfer unit 400. The liquid treatment unit 500 may treat the substrate by supplying a treating liquid to a central region of the rotating substrate. At least one of the liquid treatment units 500 may perform a coating process of forming a coating film on the substrate by supplying a photoresist liquid to a central region of the rotating substrate. In addition, at least one of the liquid treatment units 500 may perform a developing process of supplying a developing liquid to the central region of the rotating substrate.

The heating unit 600 may heat the substrate. The heating unit 600 may perform a heating process for heating the substrate between the coating process and an exposing process, and between the exposing process and the developing process, and after the developing process. A detailed description of the heating unit 600 will be described later.

The interface unit 700 may connect the substrate treating apparatus 10 to an outer exposure apparatus (not shown). The interface unit 700 may include an interface robot which transfers the substrate between the rear buffer unit 320 and an outer exposure apparatus.

The control unit 900 may control components of the substrate treating apparatus 10. For example, the control unit 900 may control at least one of a load port unit 100, an index unit 200, a buffer unit 300, a transfer unit 400, a liquid treating unit 500, a heating unit 600, and an interface unit 700. The controller 900 comprise a process controller consisting of a microprocessor (computer) that executes a control of the substrate treating apparatus 1, a user interface such as a keyboard via which an operator inputs commands to manage the substrate treating apparatus, and a display showing the operation situation of the substrate treating apparatus 10, and a memory unit storing a treating recipe, i.e., a control program to execute treating processes of the substrate treating apparatus by controlling the process controller or a program to execute components of the substrate treating apparatus based on data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

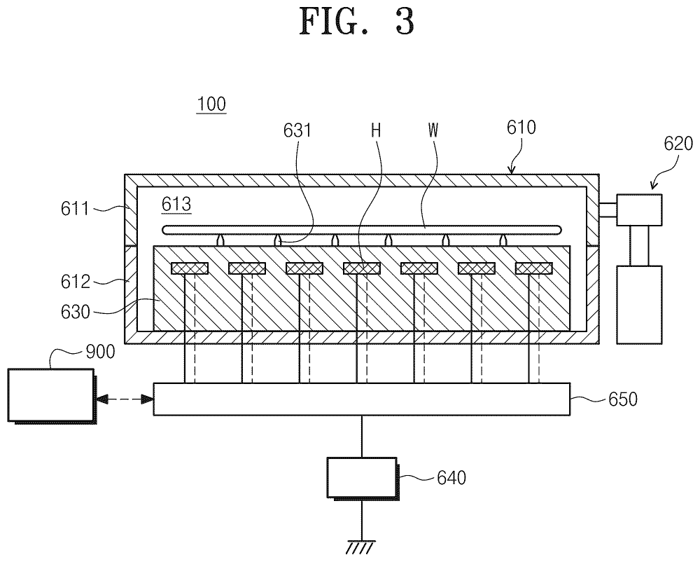

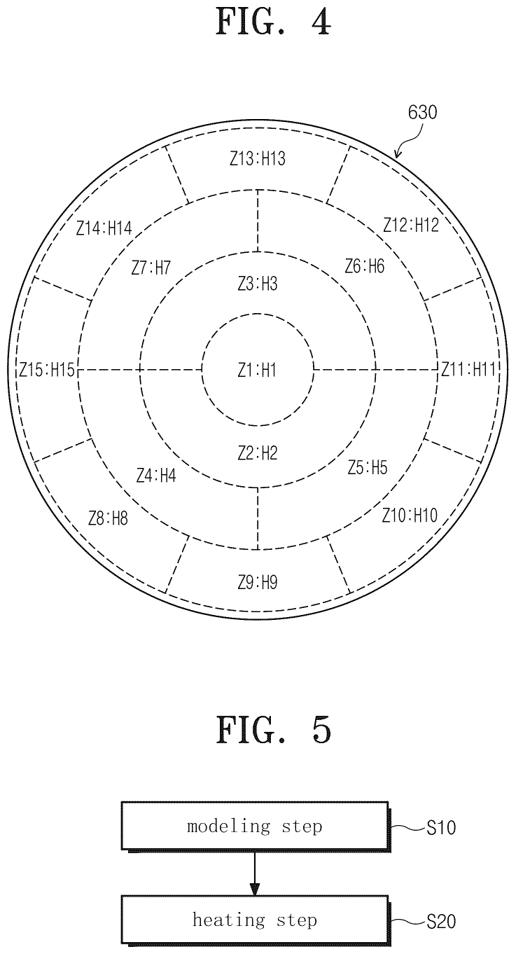

FIG. 3 is a cross-sectional view of the heating unit of FIG. 2, and FIG. 4 is a view showing for explaining an installation position of a heater installed for each region of the heating plate of FIG. 3.

Referring to FIG. 3 and FIG. 4, the heating unit 600 according to an embodiment of the inventive concept may include a housing 610, a lifting/lowering assembly 620, a heating plate 630, a heater H, a power supply 640, and a temperature controller 650.

The housing 610 may form a heating space 613 in which the substrate W is heated. The housing 610 may include a top housing 611 and a bottom housing 612. The top housing 611 and the bottom housing 612 may be combined with each other to form a heating space 613. The top housing 611 may have a cylindrical shape with an open bottom part, and the bottom housing 612 may have a cylindrical shape with an open top part.

The lifting/lowering assembly 620 may open or seal the heating space 613. The lifting/lowering assembly 620 may be configured to lift and lower any one of the top housing 611 and the bottom housing 612. For example, the lifting/lowering assembly 620 may open or seal the heating space 613 by moving the top housing 611 in the up/down direction.

An opening of the heating space 613 may be performed if the heating space 613 of the substrate W is taken in or taken out. A sealing of the heating space 613 may be performed while a heating process of the substrate W is performed. The substrate W may be taken into and/or taken out of the heating space 613 by a transfer assembly (not shown) which may be additionally provided by the transfer unit 400 or the heating unit 600.

The heating plate 630 may support the substrate W. A plurality of support pins 631 in contact with a bottom surface of the substrate W may be disposed on the heating plate 630. The plurality of support pins 631 may be disposed to be spaced apart from each other on a top surface of the heating plate 630 so as to stably support the substrate W. The heating plate 630 may stably support the substrate W through the plurality of support pins 631 installed on the heating plate 630.

In addition, the heating unit 600 may further include a lift pin assembly (not shown) capable of lifting/lowering the substrate W. The heating plate 630 may have a lift pin hole through which a lift pin of the lift pin assembly may move in the up/down direction.

The heating plate 630 may be formed of a material having an excellent thermal conductivity. For example, the heating plate 630 may be provided with a material including a metal. At least one heater H may be installed on the heating plate 630. The heater H may be provided with a material capable of generating a heat. The heater H may be provided as a heating wire generated by receiving a power from a power source 640 to be described later. A plurality of heaters H may be installed on the heating plate 630. The plurality of heaters H may be disposed at heat different regions of the substrate W.

For example, the heater H installed on the heating plate 630 may include a first heater H1 to a fifteenth heater H15. The first heater H1 may be installed at a position corresponding to a first region Z1 of the substrate W to heat the first region Z1 of the substrate W. Similarly, a second heater H2 to the fifteenth heater H15 may be installed at positions corresponding to a second region Z2 to a fifteenth region Z15 of the substrate W to heat a corresponding region of the substrate W, respectively.

The power source 640 may apply a power to the heaters H. The power source 640 may be a DC or a AC power source that applies the power to the heaters H.

The temperature controller 650 may control the power applied by the power source 640 to the heaters H. For example, the controller 650 may have a plurality of switches corresponding to each of the heaters H. The temperature controller 650 may control whether the power is applied to each heater H by turning on/off each switch based on a control signal transmitted from the control unit 900.

In addition, the temperature controller 650 may control a temperature of the heater H by adjusting a time at which the power is applied to the heaters H. For example, if the temperature of the first heater H1 is to be increased, the temperature of the first heater H1 is increased by increasing a time at which a switch corresponding to the first heater H1 is turned on, and if the temperature of the first heater H1 is to be decreased, a time at which the switch H1 is turned on shortened or the switch H1 is turned off.

In the above-described example, the temperature controller 650 includes a plurality of switches and adjusts the temperature of the heater H by adjusting a time at which the switch is turned on, but the inventive concept is not limited thereto. For example, the temperature controller 650 may include a circuit including multiple variable resistors corresponding to each heater H, and may adjust the temperature of the heater H by changing a magnitude of a current transferred to each heater H by adjusting the magnitude of variable resistors.

In addition, the temperature controller 650 may include a resistance measurement circuit capable of measuring a resistance of the heater H. For example, the resistance measurement circuit capable of measuring the resistance of the heater H is provided to correspond to each heater H, and a closed circuit may be configured with each heater H. A resistance value of the heater H may be measured based on a magnitude of the current flowing through the closed circuit. The resistance value of the heater H has a proportional relationship with the temperature of the heater H (e.g., a positive temperature coefficient characteristic in which the resistance increases if the temperature increases if the heater H is provided as metal material) or an inverse relationship with the temperature of the heather H (e.g. a positive temperature coefficient characteristic in which the resistance decreases if the temperature increases if the heater H is provided as a semiconductor or an oxide material), and a current temperature of the heater H may be derived based on a material of the heater H and a current resistance value of the heater H. A calculation of the current temperature of the heater H based on the measured resistance value of the heater H may be performed by the temperature controller 650, or the resistance value of the heater H may be transferred to the control unit 900 and calculated by a program stored in the control unit 900.

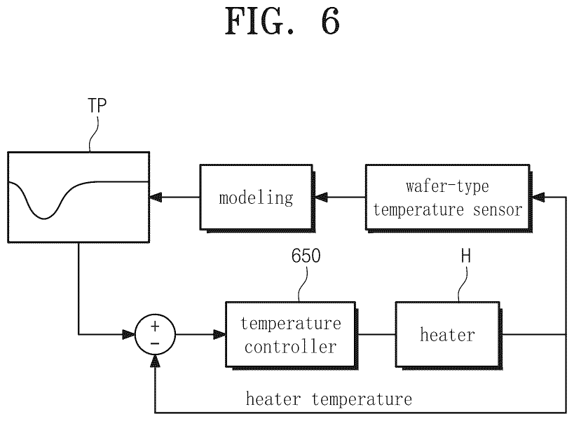

FIG. 5 is a flowchart schematically showing a substrate treating method according to an embodiment of the inventive concept, and FIG. 6 is a block view showing a modeling step and a heating step of FIG. 5.

Referring to FIG. 3 to FIG. 6, a substrate treatment method according to an embodiment of the inventive concept may include a modeling step S10 and a heating step S20.

The modeling step S10 may be a step of modeling a target temperature profile of each heater H to be used in the heating step S20 to be described later. A plurality of temperature sensors are installed in the modeling step S10, and a wafer-type sensor having the same or similar shape as a substrate W to be treated may be used. In the modeling step S10, the wafer-type sensor may be seated on the heating plate 630, and a temperature change (wafer temperature information) of each region of the wafer-type sensor obtained from the wafer-type sensor, and a temperature change information (heater temperature information) of each heater H obtained through the temperature controller 650 and/or control unit 900 may be obtained. In the modeling step S100, an obtained wafer temperature information and a heater temperature information may be collected several times in a plurality.

The target temperature profile generated in the modeling step S10 may be generated for each heater H. For example, in the modeling step S10, a first target temperature profile corresponding to a first heater H1, a second target temperature profile corresponding to a second heater H2, . . . , a fifteenth target temperature profile corresponding to a fifteenth heater H51 may be generated.

In the heating step S20, the temperature of the heater H may be controlled based on the target temperature profile of each heater H generated in the modeling step S10. For example, in the heating step S20, the temperature of the heater H is measured at unit intervals, and if the measured temperature of the heater H differs from the target temperature of the target temperature profile of the heater H, the control unit 900 can generate a control signal to control the temperature controller 650 so that the temperature of the heater H reaches the target temperature of the target temperature profile. If the temperature of the heater H is measured and the measured temperature differs from the target temperature, a control operation for controlling the temperature of the heater H may be performed at regular time intervals. In order to increase the temperature of the heater H, a time at which the switch is turned on at a corresponding time interval may be increased, and in order to relatively lower the temperature of the heater H, a time at which the switch is turned on at the corresponding time interval may be shortened.

The heating step S20 may be performed after the liquid treatment unit 500 performs a coating process of applying a photosensitive liquid on the substrate W and an exposing process performed by an outer exposure apparatus. The exposing process may be an exposing process using an ArF or an EUV.

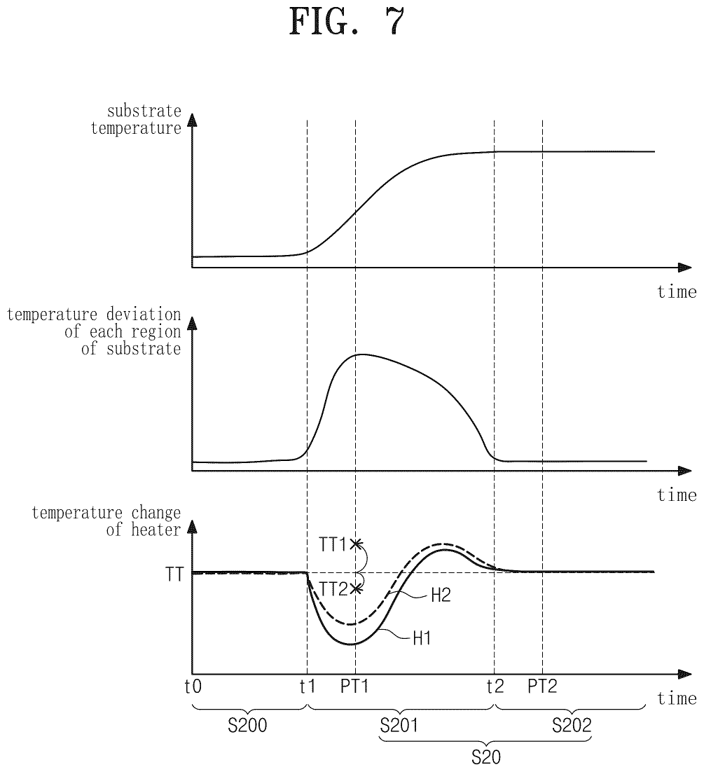

FIG. 7 is a graph showing a modeling method of a target temperature profile generated in the modeling step of FIG. 5. FIG. 7 illustrates a temperature change of the heaters H over time, a temperature change of the substrate over time, and a temperature deviation change of each region of the substrate over time if the target temperatures of the heaters H are constantly maintained at a set temperature TT.

Referring to FIG. 3, FIG. 4, and FIG. 7, hereinafter, a section before the substrate W is placed on the heating plate 630 is referred to as a pre-treatment section S200, t0˜t1, a transitional period which is an early section among the section at which the heating step S20 for heating the substrate W is performed is referred to as a first section S201˜t1˜t2, and a second section for heating the substrate W which is a later section among a stabilization period at the heating step S20 is defined as a second section S202. t2˜.

In a temperature change graph of the substrate W over time, an average temperature of the substrate W may be shown. In a temperature deviation change graph for each region of the substrate over time, a difference between a maximum temperature and a minimum temperature in one substrate W may be shown. The temperature change of the heater H over time may be shown in the temperature change of each heater H over time, and for convenience of explanation, only the temperature change of the first heater H1 and the second heater H2 among the heaters H is shown over time, and the temperature change of the third heater H3 to fifteenth heater H15 is omitted.

Referring to the temperature change graph of the substrate W over time, if a substrate W having a relatively low temperature is seated on the heating plate 630, the substrate W receives a heat from the heaters H, the temperature of the substrate W is continuously increased, and the temperature of the substrate W is maintained relatively constant if the target temperature is reached.

Referring to the temperature deviation graph by region of the substrate W over time, the temperature deviation of the substrate W by region is relatively small in a second section S202, but the temperature deviation of the substrate W is relatively large in a first section S101, at which the temperature of the heaters H changes rapidly.

Referring to the temperature change graph of the heaters H over time, if the substrate W is placed on the heating plate 630, the temperature of the heaters H installed on the heating plate 630 may also be lowered by placing the substrate W on the heating plate 630. For example, at a first time point PT1 of the first section S201, a temperature drop of the first heater H1 may be greater than the temperature drop of the second heater H2. The temperature drop of the heaters H may be affected by the temperature of the substrate W.

From a large temperature drop of the first heater H1, it may be estimated that a temperature of a first region Z1 of the substrate W corresponding to the first heater H1 is low. Similarly, from a small temperature drop of the second heater H2, it can be estimated that a temperature of a second region Z2 of the substrate W corresponding to the second heater H2 is high.

If the target temperature of the heaters H is set to a constant set temperature TT, the temperature of the heaters H is feedback-controlled to reach the set temperature TT without considering a temperature change difference between them, and thus a difference in a temperature change tendency of the heaters H is generated. The difference in the temperature change tendency of the heaters H means that an amount of heat transferred to the substrate W per unit time for each heater H is different, making it difficult to uniformly treat the substrate W by making a temperature deviation large for each region of the substrate W.

Accordingly, according to an embodiment of the inventive concept, the target temperature of the heaters H is not set to the set temperature TT which is constant, but the target temperature is set differently in the first section S201 and the second section S202, thereby solving the above-mentioned problem.

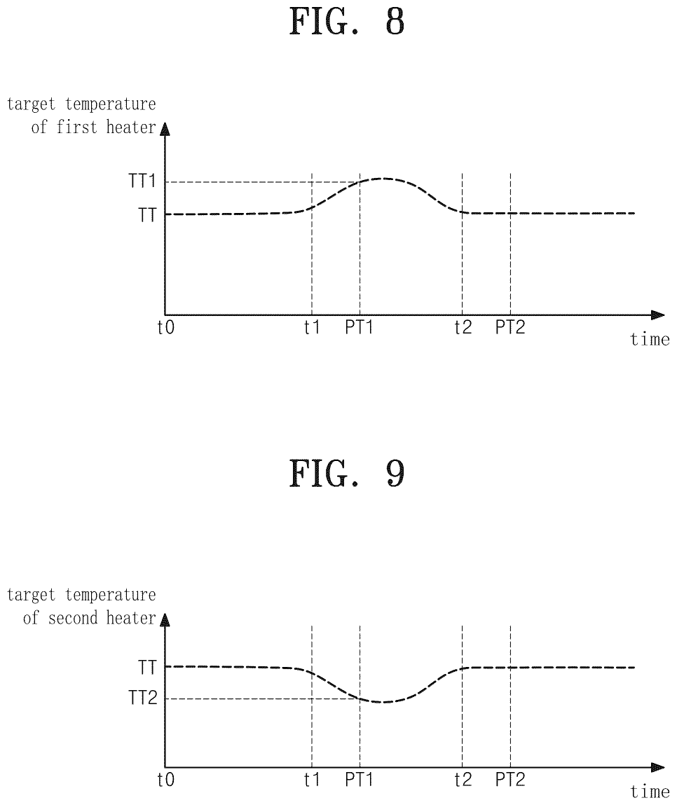

For example, as described above, the temperature drop of the first heater H1 is greater than the temperature drop of the second heater H2. This may mean that a temperature of the first region Z1 of the substrate W corresponding to the first heater H1 is low. Since the first region Z1 has a relatively low temperature, the first region Z1 should be heated more than another region (e.g., than the second region Z2). To this end, the target temperature of the first heater H1 is modeled to the first target temperature TT1 which is higher than the set temperature TT at the first time point PT1 belonging to the first section S201 (see FIG. 8). In the case of modeling in this way, since a difference between the measured temperature of the first target temperature TT1 and the first heater H1 increases, the control unit 900 may control the temperature controller 650 to further increase the temperature of the first heater H1.

Conversely, the temperature drop of the second heater H2 is smaller than the temperature drop of the first heater H1. This may mean that the temperature of the second region Z2 of the substrate W corresponding to the second heater H2 is relatively high. Since the second region Z2 has a relatively high temperature, the second region Z2 should be heated a little more (e.g., compared to the first region Z1). To this end, the target temperature of the second heater H2 is modeled to the second target temperature TT2 higher than the set temperature TT at the first time point PT1 belonging to the first section S201 (see FIG. 9). In the case of modeling in this way, since the difference between a measurement temperature of the second target temperature TT2 and the second heater H2 increases, the control unit 900 may control the temperature controller 650 so that a temperature of the second heater H2 increases less.

At the second time point PT2 belonging to the second period S202, which is a stabilizing period, the target temperatures of the first heater H1 and the second heater H2 may be set to the set temperature TT.

In addition, if the temperature of the first target temperature TTI is set excessively high or the second target temperature TT2 is set excessively low, the temperature of the heaters H may change excessively, further increasing a temperature deviation between the heaters H. In addition, a rise speed and a fall speed of a temperature per unit time may be different for each heater H. Accordingly, according to an embodiment of the inventive concept, the target temperature of the heaters H at the first time point PT1 in the first section S201 may be set with at least one of a temperature rise speed and a temperature fall speed of each heater H, and a temperature drop if the substrate W is seated on the heating plate 630 as a parameter.

According to an embodiment of the inventive concept, a temperature change difference tendency between the heaters H, which occurs if the substrate W is placed on the heating plate 630, can be minimized as quickly as possible by changing the target temperature of the heaters H at the first time point PT1 and the second time point PT2. As the temperature change difference tendency between the heaters H is rapidly resolved, the heaters H may have the same temperature change difference tendency in a relatively early time. Accordingly, it helps to uniformly treat the substrate W by shortening a time difference between the heaters H of a heat amount per unit time transferred to the substrate W.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating method comprising:
measuring a temperature of a plurality of heaters installed on a heating plate for heating a substrate; and
heating the substrate by adjusting an output of the heater based on a difference between a measured temperature of each heater and a target temperature of each heater which was previously modelled, and
wherein a target temperature of a first heater among the heaters at a first time point is set differently from the target temperature of the first heater at a second time point which is later than the first time point.

2. The substrate treating method of claim 1, wherein the target temperature of the first heater among the heaters at the first time point is set lower than the target temperature of the first heater at the second time point.

3. The substrate treating method of claim 2, wherein the target temperature of the second heater among the heaters at the first time point is set differently from the target temperature of the second heater at the second time point.

4. The substrate treating method of claim 3, wherein the target temperature of the second heater among the heaters at the first time point is set higher than the target temperature of the second heater at the second time point.

5. The substrate treating method of claim 4, wherein the first heater has a temperature drop smaller than the second heater if the substrate is seated on the heating plate.

6. The substrate treating apparatus of claim 5, wherein the target temperature of the first heater and the second heater at the first time point, is based on at least one among a rise speed and a drop speed of a temperature of the second heater, and a temperature drop if the substrate is seated on the heating plate.

7. The substrate treating method of claim 1, wherein the measured temperature of each heater is calculated based on a measured resistance value of the heater.

8. The substrate treating method of claim 1, wherein the substrate is heated by being seated on the heating plate after a coating process of coating a photoresist liquid on the substrate is performed and a subsequent exposing process is performed after the coating process.

9. The substrate treating method of claim 1, wherein the first time point belongs to a transitional period which is an early period among a substrate heating section and the second time point belongs to a stabilization period among a later period among the substrate heating section.

10. The substrate treating method of claim 9, wherein a temperature change of the heater at the transitional period is larger than a temperature change of the heater in the stabilization period.

11. A method for controlling a substrate treating apparatus comprising:
measuring a temperature of a plurality of heaters installed on a heating plate;
adjusting an output of the heater based on a difference between a measured temperature of each heater and a target temperature of each heater which was previously modelled, and
wherein a target temperature of a first heater among the heaters at a first time point is set differently from the target temperature of the first heater at a second time point which is later than the first time point.

12. The method for controlling the substrate treating apparatus of claim 11, wherein the first time point belongs to a transitional period which is an early period among a substrate heating section and the second time point belongs to a stabilization period among a later period among the substrate heating section.

13. The method for controlling the substrate treating apparatus of claim 12, wherein the target temperature of the first heater among the heaters at the first time point is set lower than the target temperature of the first heater at the second time point.

14. The method for controlling the substrate treating apparatus of claim 13, wherein the target temperature of the second heater among the heaters at the first time point is set higher than the target temperature of the second heater at the second time point.

15. The method for controlling the substrate treating apparatus of claim 14, wherein the first heater has a temperature drop smaller than the second heater if the substrate is seated on the heating plate.

16. The method for controlling the substrate treating apparatus of claim 15, wherein the target temperature of the first heater and the second heater at the first time point, is based on at least one among a rise speed and a drop speed of a temperature of the second heater, and a temperature drop if the substrate is seated on the heating plate.

17.-20. (canceled)
